(19) United States
(12) Patent Application Publication
(10) Pub. No.: US 2015/0144918 A1
(43) Pub. Date: May 28, 2015

(54) METHOD OF MANUFACTURING OPTICAL FILM FOR REDUCING COLOR SHIFT, ORGANIC LIGHT-EMITTING DISPLAY APPARATUS USING OPTICAL FILM FOR REDUCING COLOR SHIFT, AND METHOD OF MANUFACTURING THE SAME

(71) Applicant: Samsung Electronics Co., Ltd., Suwon-Si (KR)

(72) Inventors: Eun-hyoung CHO, Hwaseong-si (KR); Woong KO, Hwaseong-si (KR); Jae-kwan KIM, Hwaseong-si (KR); Chang-youl MOON, Suwon-si (KR); Hong-shik SHIM, Seoul (KR); In-kyeong YOO, Yongin-si (KR); Chul-ho JEONG, Gwangju (KR)

(21) Appl. No.: 14/549,800

(22) Filed: Nov. 21, 2014

(30) Foreign Application Priority Data
Nov. 22, 2013 (KR) 10-2013-00143152

(51) Int. Cl. H01L 51/56; H01L 51/52; H01L 27/32; B29D 11/00; B29C 33/38

(52) U.S. Cl. CPC H01L 51/56; B29D 11/00788; B29C 33/3885; H01L 27/3206; H01L 51/5253; H01L 51/5265; H01L 51/5275; B29K 2029/04
USPC 257/40; 264/1.7; 438/27

(57) ABSTRACT

An optical film manufacturing method includes forming a master in which a shape corresponding to a plurality of micro-lens patterns is engraved, forming a low refractive index pattern layer in which the plurality of micro-lens patterns are formed, by using the master, forming a high refractive index material layer that has a higher refractive index than a refractive index of the low refractive index pattern layer, and imprinting the low refractive index pattern layer on the high refractive index material layer to form a high refractive index pattern layer, on a first surface of a substrate.

### RELATED APPLICATIONS

This application claims priority from Korean Patent Application No. 10-2013-0143152, filed on Nov. 22, 2013, in the Korean Intellectual Property Office, the disclosure of which is incorporated herein in its entirety by reference.

### BACKGROUND

1. Field

Example embodiments relate to optical films for reducing color shift and/or organic light-emitting display apparatuses using the same.

2. Description of the Related Art

Organic light-emitting diodes (OLEDs) include an anode, an organic emission layer, and a cathode. When a voltage is applied between the anode and the cathode, holes are injected from the anode into the organic emission layer, and electrons are injected from the cathode into the organic emission layer. The holes and electrons injected into the organic emission layer are recombined in the organic emission layer to generate excitons, and the excitons are shifted from an excited state to a ground state to thus emit light.

In the OLEDs, since a light-emitting material is an organic material, a disadvantage of reduced service life due to deterioration of the material is a fundamental issue in the development of OLED technology, and many technologies are being proposed to address this issue.

A micro-cavity structure in which light resonates at a certain wavelength to increase a light intensity that emits the light to the outside, is one such technology. That is, a distance between an anode and a cathode is designed to match a representative wavelength of each of red (R), green (G), and blue (B) wavelengths, and thus, only light corresponding thereto resonates to be emitted to the outside, and other wavelengths are weakened. As a result, an intensity of light emitted to the outside is strengthened and sharpened, thereby increasing luminance and color purity. Furthermore, the increase in luminance leads to low power consumption, thereby increasing service life.

On the other hand, in the micro-cavity structure, a wavelength to be amplified by a film thickness of an organic deposition material is determined, and a path length of light is along a side instead of a front. For this reason, an effect similar to the film thickness of the organic deposition material being changed occurs, causing a change in an amplified wavelength.

That is, as a viewing angle is tilted from a front to a side, the maximum resonance wavelength is shown in a short wavelength, and thus, color shift occurs toward the short wavelength. For example, a blue shift phenomenon in which white is shown at the front and bluish white at the side occurs.

Optical films of various structures for reducing color shift, which are each attached to an OLED panel, are being proposed for reducing color shift based on a viewing angle. The optical films for reducing color shift include a micro-lens pattern having a high aspect ratio, and thus, in manufacturing the optical film, defects such as outgassing and void formation occur in a process of filling the micro-lens pattern with a filling material, and hardening and releasing the filling material.

### SUMMARY

At least one example embodiment relates to methods of manufacturing an optical film for reducing color shift, organic light-emitting display apparatuses using the optical film for reducing color shift, and/or methods of manufacturing the same.

Additional example embodiments will be set forth in part in the description which follows and, in part, will be apparent from the description, or may be learned by practice of the example embodiments.

According to at least one example embodiment, an optical film manufacturing method includes forming a master in which a shape corresponding to a plurality of micro-lens patterns is engraved, forming a low refractive index pattern layer in which the plurality of micro-lens patterns are formed, by using the master, and forming a high refractive index material layer that has a higher refractive index than a refractive index of the low refractive index pattern layer, and imprinting the low refractive index pattern layer on the high refractive index material layer to form a high refractive index pattern layer, on a first surface of a substrate.

After the imprint process, a release process that separates the low refractive index pattern layer from the high refractive index pattern layer may not be performed.

According to at least one example embodiment, the forming of a low refractive index pattern layer may include forming a low refractive index material layer on a base film, disposing the master on the low refractive index material layer, pressuring and hardening the master to form the low refractive index pattern layer, and separating the master from the low refractive index pattern layer.

The optical film manufacturing method may further include, after the high refractive index pattern layer is formed, separating the base film from the low refractive index pattern layer.

The forming of a master may include forming a plurality of sub molds that are each formed of a resin material and have the same shape as the shape of an equally divided portion of the master, tiling the plurality of sub molds to form a large-area mold, and performing a duplication process of the large-area mold to form a shape of the large-area mold with a metal material.

The forming of a plurality of sub molds may include, forming a metal mold in which a shape corresponding to the sub mold is embossed, imprinting the shape of the metal mold on a first polymer material, separating the metal mold from the first polymer material to form one sub mold, and repeating the imprinting for a second polymer material.

The forming of a metal mold may include forming a silicon master in which the plurality of micro-lens patterns are formed, and performing a duplication process of the silicon master to form the same shape as a shape of the silicon master with a metal material.

The forming of a silicon master may use an electron beam lithography method or a laser interference lithography method.

The performing of a duplication process of the silicon master may include forming a soluble polymer layer on a base film, disposing the silicon master on the soluble polymer layer, pressurizing and hardening the silicon master to form a pattern polymer layer, separating the silicon master from the pattern polymer layer, coating a metal material on the pattern polymer layer, hardening the metal material, and dissolving the pattern polymer layer.

The soluble polymer layer may be formed of polyvinylalcohol.

The performing of a duplication process of the large-area mold may include forming a soluble polymer layer on a base film, disposing the large-area mold on the soluble polymer layer, pressurizing and hardening the large-area mold to form a pattern polymer layer, separating the pattern polymer layer from the large-area mold, coating a metal material on the pattern polymer layer, hardening the metal material, and dissolving the pattern polymer layer.

The soluble polymer layer may be formed of polyvinylalcohol.

The forming of a low refractive index pattern layer and the forming of a high refractive index pattern layer may be performed according to a roll printing process.

The optical film manufacturing method may further include forming an anti-reflection layer on a second surface facing the first surface, on the substrate.

The optical film manufacturing method may further include, before forming the anti-reflection layer, forming a circular polarization film, which includes a phase conversion layer and a linear polarization layer, on the second surface.

The optical film manufacturing method may further include, before forming the anti-reflection layer, forming a transmittance adjusting layer on the second surface facing the first surface.

According to at least one example embodiment, a method of manufacturing an organic light-emitting display apparatus includes preparing an organic light-emitting panel, including a plurality of organic emission layers, each of which emits light having different wavelengths and has a micro-cavity structure causing a resonance phenomenon from light having a corresponding wavelength, and a sealing layer that covers the plurality of organic emission layers, on a substrate, manufacturing an optical film according to the method, and bonding the optical film to the organic light-emitting panel.

The sealing layer and the low refractive index pattern layer may be formed of the same material.

According to at least one example embodiment, an organic light-emitting display apparatus includes a first substrate, a plurality of organic emission layers on the first substrate, each of which emits light having different wavelengths, and has a micro-cavity structure causing a resonance phenomenon from light having a corresponding wavelength, a sealing layer that covers the plurality of organic emission layers, a low refractive index pattern layer that is formed on the sealing layer, and in which a plurality of micro-lens patterns are embossed, a high refractive index pattern layer that is formed of a material, having a higher refractive index than a refractive index of the low refractive index pattern layer, on the low refractive index pattern layer, and in which a shape corresponding to the plurality of micro-lens pattern is engraved, and a second substrate that is formed on the high refractive index pattern layer.

### BRIEF DESCRIPTION OF THE DRAWINGS

These and/or other example embodiments will become apparent and more readily appreciated from the following description of the example embodiments, taken in conjunction with the accompanying drawings in which:

FIGS. 1A and 1B are cross-sectional views illustrating a schematic structure of an optical film to be manufactured, and respectively illustrate a light path, through which light vertically incident on the optical film is output, and a light path through which light obliquely incident on the optical film is output;

FIGS. 2A to 2F, FIGS. 3A to 3I, and FIGS. 4A to 4G are illustrations of methods of manufacturing an optical film according to example embodiments;

FIGS. 5A to 5C are cross-sectional views illustrating example structures of an optical film manufactured by a method of manufacturing the optical film according to an example embodiment;

FIGS. 6A to 6B are views for describing a method of manufacturing an organic light-emitting display apparatus according to an example embodiment;

FIGS. 7A to 7D are illustrations of methods of manufacturing an organic light-emitting display apparatus according to a comparative example; and

FIG. 8 illustrates a method of manufacturing an organic light-emitting display apparatus according to an example embodiment.

### DETAILED DESCRIPTION

Reference will now be made in detail to example embodiments illustrated in the accompanying drawings, wherein like reference numerals refer to like elements throughout. In this regard, the example embodiments may have different forms and should not be construed as being limited to the descriptions set forth herein. Accordingly, the example embodiments are merely described below, by referring to the figures. Expressions such as “at least one of,” when preceding a list of elements, modify the entire list of elements and do not modify the individual elements of the list.

Example embodiments may impose various transformations that may have various example embodiments, and specific example embodiments illustrated in the drawings will be described in detail in the detailed description. The effects and features of the example embodiments will become apparent from the following description with reference to the accompanying drawings, which is set forth hereinafter. The example embodiments may, however, may be embodied in different forms and should not be construed as being limited to the examples set forth herein.

Hereinafter, example embodiments will be described in detail with reference to the accompanying drawings. In addition, in the present specification and drawings, like reference numerals refer to like elements throughout, and thus, redundant descriptions are omitted.

It will be understood that when an element is referred to as being “on,” “connected” or “coupled” to another element, it can be directly on, connected or coupled to the other element or intervening elements may be present. In contrast, when an element is referred to as being “directly on,” “directly connected” or “directly coupled” to another element, there are no intervening elements present. As used herein the term “and/or” includes any and all combinations of one or more of the associated listed items. Further, it will be understood that when a layer is referred to as being “under” another layer, it can be directly under or one or more intervening layers may also be present. In addition, it will also be understood that when a layer is referred to as being “between” two layers, it can be the only layer between the two layers, or one or more intervening layers may also be present.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. In the following example embodiments, the singular forms “a”, “an” and “the” are intended to include the plural forms as well, unless the context clearly indicates otherwise.

In the following example embodiments, it should be further understood that the terms “comprises”, “comprising”, “has”, “having”, “includes” and/or “including”, when used herein, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments. Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein. As used herein, expressions such as “at least one of,” when preceding a list of elements, modify the entire list of elements and do not modify the individual elements of the list.

In the drawings, the dimensions of layers and regions are exaggerated or reduced for clarity of illustration. For example, a dimension and thickness of each element in the drawings are arbitrarily illustrated for clarity, and thus, embodiments of the present invention are not limited thereto.

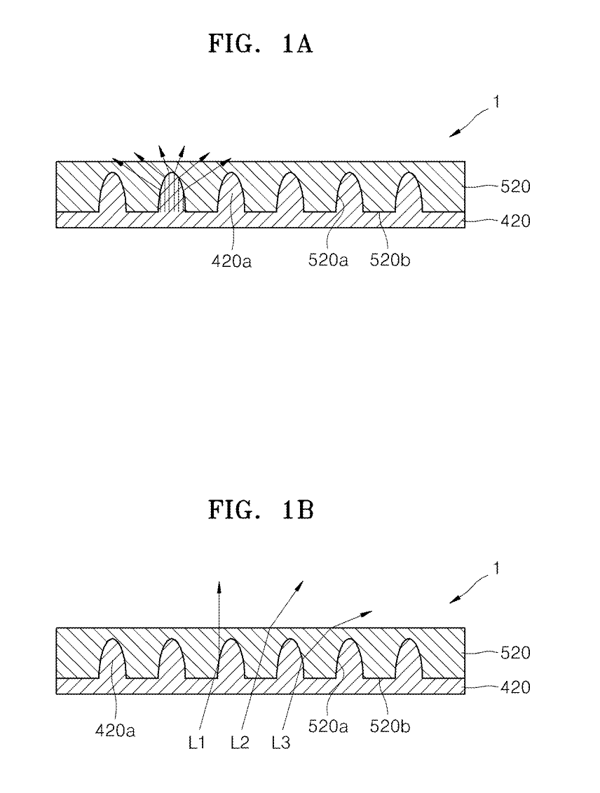

According to at least one example embodiment, FIGS. 1A and 1B are cross-sectional views illustrating a schematic structure of an optical film 1 to be manufactured, and respectively illustrate a light path through which light vertically incident on the optical film 1 is output, and a light path through which light obliquely incident on the optical film 1 is output.

The optical film 1 refracts and outputs light, which is incident in one direction, in various directions depending on an incident position of the light, and combines the light. First, an example configuration of the optical film 1 will now be described in detail.

The optical film 1 includes a low refractive index pattern layer 420, in which a plurality of micro-lens patterns 420a are embossed, and a high refractive index pattern layer 520 in which a shape corresponding to the plurality of micro-lens patterns 420a is engraved on the low refractive index pattern layer 420. Each of the micro-lens patterns 420a may have a shape formed of a curved surface in which a depth is greater than a width. The plurality of micro-lens patterns 420a may be patterns in which a plurality of stripe patterns are one-dimensionally arranged or a plurality of dot patterns are two-dimensionally arranged.

The high refractive index pattern layer 520 may be formed of a material (for example, a transparent plastic material) having a refractive index greater than about 1. Also, the high refractive index pattern layer 520 may be formed of a transparent plastic material containing an optical diffuser or an optical absorber. The optical diffuser may use a diffusive bead, and the optical absorber may use a black dye such as, for example, carbon black. The optical diffuser planarizes a peak which occurs in color shifts (Δu′v′) and a luminance profile with respect to angle, due to a certain groove, thereby enhancing a visual characteristic. Also, the optical absorber may contribute to enhance a characteristic, such as contrast or color purity, by using a dye which selectively absorbs a certain wavelength or by using carbon black which absorbs most or all wavelengths of visible light.

The low refractive index pattern layer 420 may be formed of a resin material having a lower refractive index than the refractive index of the high refractive index pattern layer 520, or may be formed of a transparent plastic material containing an optical diffuser or an optical absorber. The optical diffuser may use a diffusive dye, and the optical absorber may use a black dye such as, for example, carbon black.

A boundary surface between the low refractive index pattern layer 420 and the high refractive index pattern layer 520 forms a plurality of micro-lens patterns 420a, and includes a pattern in which a curved surface 520a and a planar surface 520b are alternated. The curved surface 520a may be formed of various aspherical surfaces such as an oval surface, a parabolic surface, a hyperbolic surface, etc.

Referring to FIG. 1A, according to at least one example embodiment, light vertically incident on the optical film 1 is refracted in different directions depending on a position contacting the curved surface 520a, and is output from the optical film 1. That is, rays having the same incident angle are refracted in various directions depending on positions reaching the curved surface 520a, and thus, light is diffused.

Referring to FIG. 1B, according to at least one example embodiment, light obliquely incident on the optical film 1 is refracted in different directions depending on an incident position. For example, light L1 which passes through the planar surface 520b and reaches the curved surface 520a in the high refractive index pattern layer 520 is substantially, mostly or completely reflected off of the curved surface 520a, and is output through the optical film 1. In such a path, an angle at which the light is output through a top of the high refractive index pattern layer 520 is less than an angle of the light incident on the optical film 1. Light L2, which passes through the planar surface 520b without passing through the curved surface 520a, is refracted such that a refractive angle is greater than an incident angle in a boundary between the high refractive index pattern layer 520 and the outside, and thus is output through the optical film 1 at a greater angle than an angle of the light incident on the optical film 1. Also, light L3 contacting the curved surface 520a in the low refractive index pattern layer 420 is refracted by the curved surface 520a, and is refracted again by the top of the high refractive index pattern layer 520, whereby the light is output through the optical film 1 at a greater refractive angle than the refractive angle of the light L2 which is output via the planar surface 520b without contacting the curved surface 520a. The incident lights L1, L2 and light L3, which are obliquely incident on the optical film 1 at the same angle, are output through the optical film 1 at different refractive angles depending on the position of the incident light.

As described above, the light passing through the optical film 1 is such that light incident on the optical film 1 at various angles is combined.

In the above description, a detailed light path through which incident light is diffused is an example only, and is exaggerated for convenience of illustration. For example, refraction of a light path which occurs in the planar surface 520b is not illustrated. Also, a light path is gradually changed depending on a refractive index difference between the high refractive index pattern layer 520 and the low refractive index pattern layer 420, an aspect ratio of the micro-lens patterns 420a, a period at which the micro-lens patterns 420a are repeatedly arranged, and a curved-surface shape of each of the micro-lens patterns 420a, and thus, the degree of combination of light or a luminance of output light may vary.

When light incident on the optical film 1 has different optical characteristics based on an angle of incidence, the above-described light combination effect leads to an effect in which light obtained by uniformly combining the optical characteristics is output. For example, when light is emitted from an organic light-emitting diode (OLED), a color shift phenomenon in which color characteristics differ based on an output angle. The light passes through the optical film 1 having the above-described structure, and degrees of color shift are combined, thereby reducing the color shift that is due to the viewing angle.

As described above, a function in which the optical film 1 reduces color shift based on a viewing angle is achieved by the micro-lens patterns 420a, and a manufacturing method according to an example embodiment is disclosed.

According to at least one example embodiment, a method of manufacturing an optical film according to an example embodiment includes forming a master in which a shape corresponding to a plurality of micro-lens patterns 420a is engraved, forming a low refractive index pattern layer in which the plurality of micro-lens patterns 420a are formed, by using the master, and imprinting the low refractive index pattern layer on a material having a higher refractive index than the refractive index of the low refractive index pattern layer to form a high refractive index pattern layer.

In the method of manufacturing an optical film according to an example embodiment, a release process that separates the low refractive index pattern layer (used as an imprinting mold) from the high refractive index pattern layer is not performed, and thus, a micro-lens pattern with reduced defects can be realized.

Hereinafter, an example method for implementing the method will be described in detail.

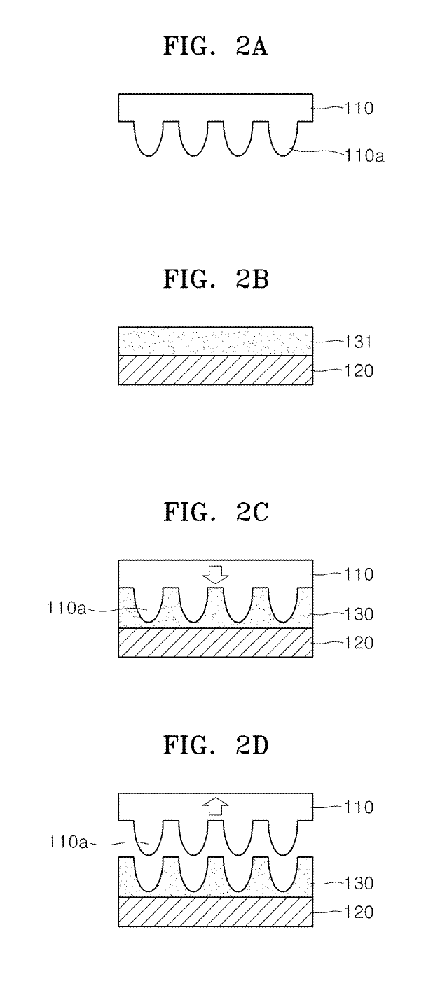

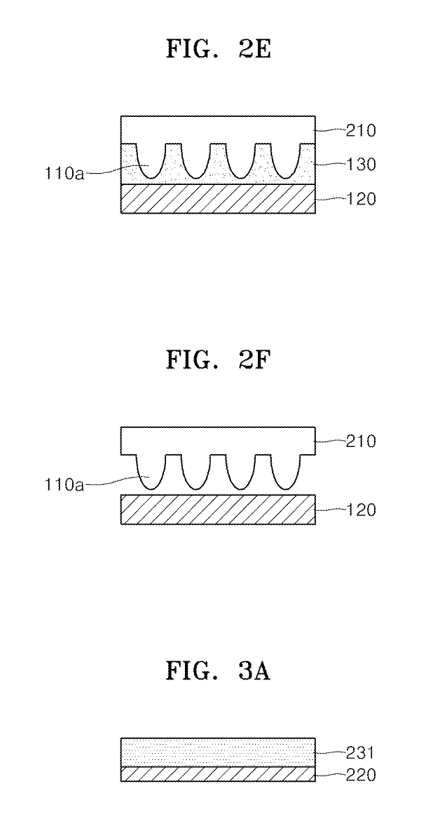

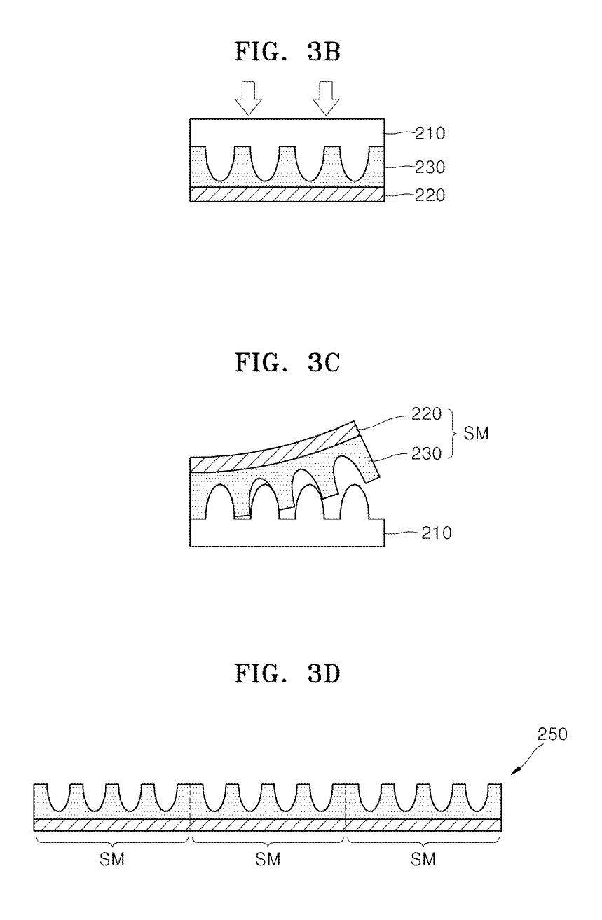

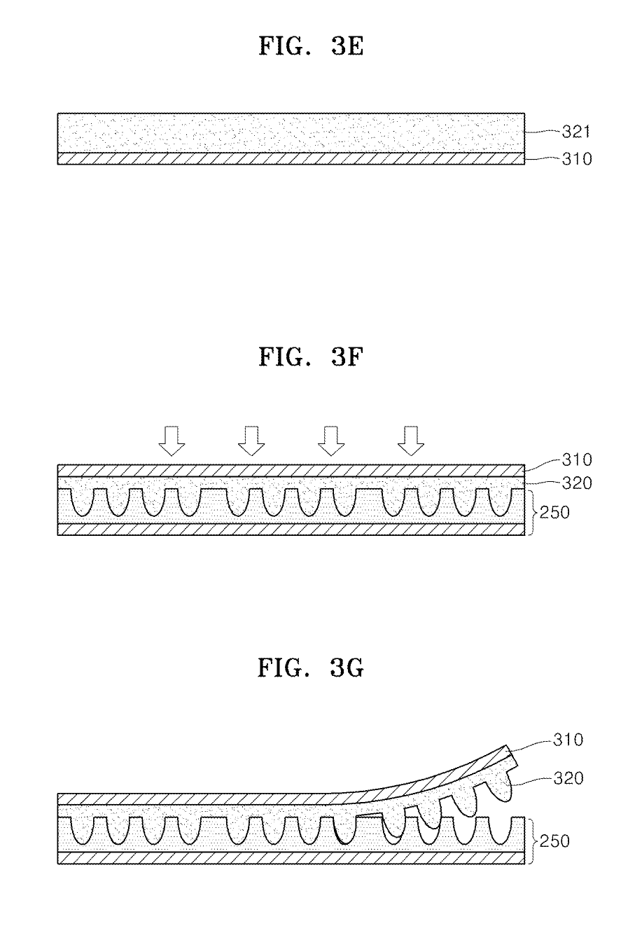

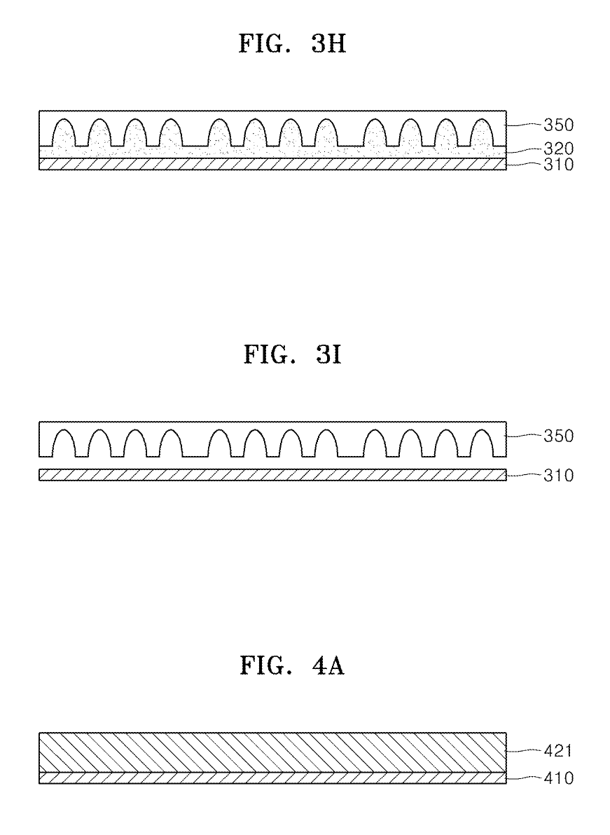

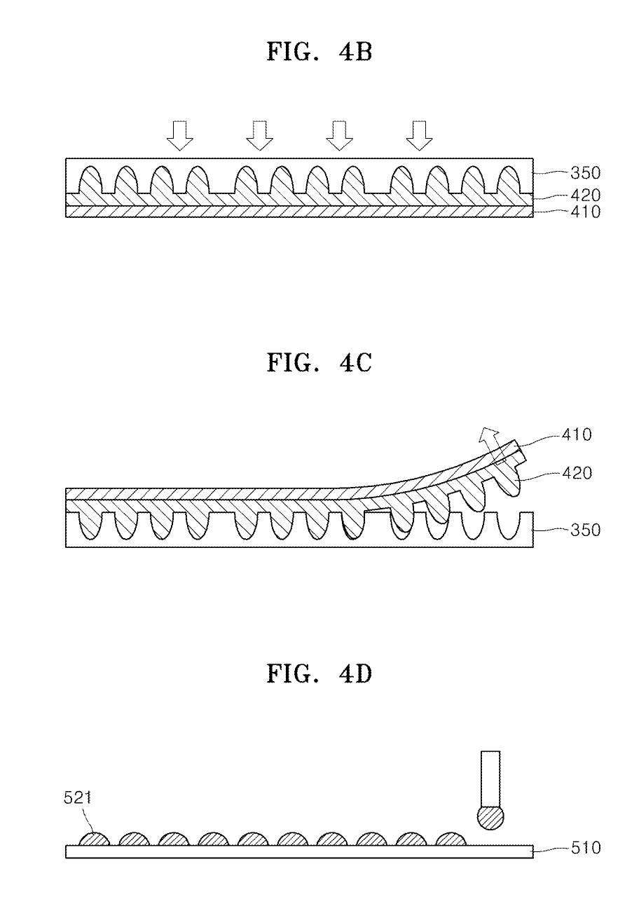

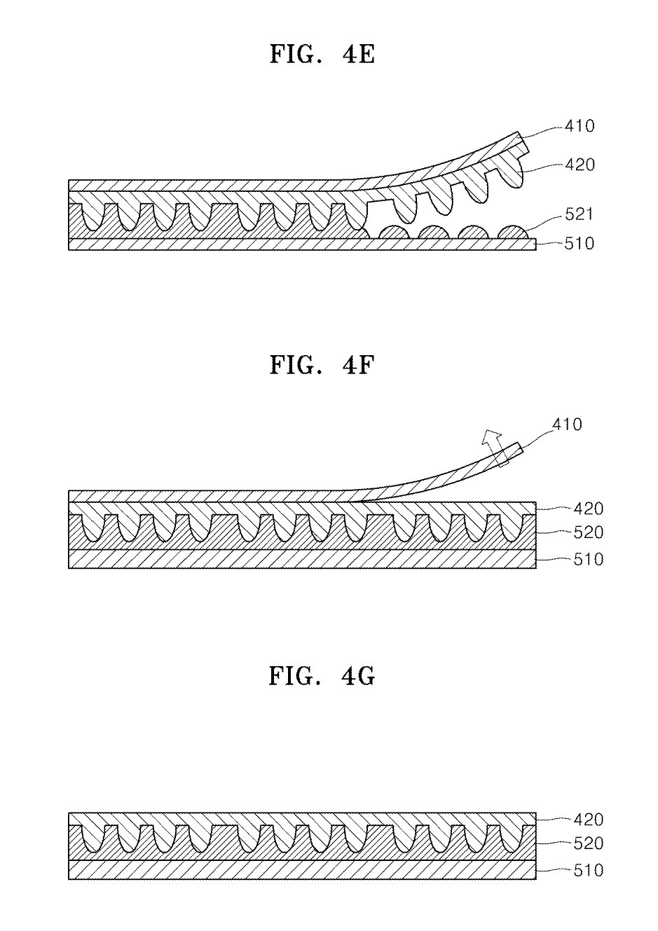

FIGS. 2A to 2F, FIGS. 3A to 3I, and FIGS. 4A to 4G are views for describing a method of manufacturing an optical film according to an example embodiment. In detail, FIGS. 2A to 2F illustrate a process that forms a silicon master in which a shape corresponding to a plurality of micro-lens patterns to be formed on an optical film is embossed, and duplicates the silicon master to form a metal mold. FIGS. 3A to 3I illustrate a process that forms a master having a large area in which a shape corresponding to a plurality of micro-lens patterns to be formed on the optical film is engraved, by using the metal mold. FIGS. 4A to 4E illustrate a process that forms a low refractive index pattern layer and a high refractive index pattern layer by using the formed master.

Referring to FIG. 2A, according to at least one example embodiment, a silicon master 110 with a micro-lens pattern 110a formed therein is prepared.

A micro-lens pattern 110a to be formed on an optical film may be precisely formed having a designed shape. To this end, the silicon master 110 may be formed by patterning and etching a silicon substrate by using an electron beam lithography method, a laser interference lithography method or other patterning and/or etching method. A process of forming the micro-lens pattern 110a typically takes time and is costly, and thus, the silicon master 100 is formed to have a small size of an equally divided plurality of optical film segments when an optical film to manufacture is equally divided in a plurality of portions.

Subsequently, referring to FIG. 2B, according to at least one example embodiment, a soluble polymer layer 131 is formed on a base film 120. The soluble polymer layer 131 may be formed of a polymer material that is dissolved by a solvent, and for example, may include polyvinylalcohol dissolvable by water.

Subsequently, according to at least one example embodiment, the silicon master 110 is disposed on the soluble polymer layer 131, and by pressurizing the silicon master 110, as illustrated in FIG. 2C, a pattern polymer layer 130 in which the shape of the silicon master 110 is patterned is formed.

Subsequently, as illustrated in FIG. 2D, according to at least one example embodiment, the silicon master 110 is separated from the pattern polymer layer 130.

Once the silicon master 110 is separated from the pattern polymer layer 130, as illustrated in FIG. 2E, according to at least one example embodiment, a metal mold 210 corresponding to a reverse shape of the pattern polymer layer 130 is formed by coating a metal material on the pattern polymer layer 130. The metal material may include, for example, nickel (Ni), but is not limited thereto. The metal mold 210 may be formed by an electroforming method or other forming method.

Subsequently, by dissolving the pattern polymer layer 130, as illustrated in FIG. 2F, according to at least one example embodiment, the metal mold 210 is separated from the base film 120. The metal mold 210 has a shape that is a duplicate of the shape of the silicon master 110 of FIG. 2A with a metal material, and thus has the same shape as the shape of the silicon master 110.

The above example process may be performed to preserve the expensive silicon master 110, and in a subsequent process, the metal mold 210 is used. As another example, a subsequent process may be performed by using the silicon master 110 without separately forming the metal mold 210.

Referring to FIG. 3A, according to at least one example embodiment, a polymer layer 231 is formed on the base film 220. An adhesion promoter may be coated on the polymer layer 231 and an adhesive force may be applied to the polymer layer 231 by using the metal mold 210. The metal mold 210 of, for example, FIG. 2F, is disposed on the polymer layer 231, and by pressurizing the metal mold 210, as illustrated in FIG. 3B, the pattern polymer layer 230 in which the shape of the metal mold 210 is imprinted is formed.

Subsequently, as illustrated in FIG. 3C, according to at least one example embodiment, the metal mold 210 is separated from the pattern polymer layer 230. To this end, an ultraviolet (UV) irradiation process that weakens adhesiveness by breaking chemical bonding of a preprocessed adhesion promoter may be performed. The base film 220 and the pattern polymer layer 230 form a sub mold (SM).

By repeating the processes of FIGS. 3B and 3C, the sub mold SM may be formed in a plurality. The number of sub molds SM may be determined so that an area occupied by the plurality of sub molds SM is equal to an area of an optical film to be manufactured.

Referring to FIG. 3D, according to at least one example embodiment, a mold 250 having a large area is formed by appending the plurality of sub molds SM next to one another. Accordingly, the large-area mold 250 has an area equal to an area of an optical film to be manufactured.

Subsequently, referring to FIG. 3E, according to at least one example embodiment, a soluble polymer layer 321 is formed on a base film 310. The soluble polymer layer 321 may be formed of a polymer material that is capable of being dissolved in a solvent, and for example, may include polyvinylalcohol dissolved in water. For example, the soluble polymer layer 321 may include an organic solvent, for example, an aromatic-based solvent, a ketone-based solvent, a halogen-based solvent, an ether-based solvent, an ester-based solvent, or an alcohol-based solvent, and in addition, may include a resin capable of being dissolved in dimethyl formamide, dimethylsulfoxide, or diethyl formamide. The resin may include, for example, a thermoplastic resin such as an acryl-based resin, a methacryl-based resin, a styrene-based resin, an epoxy-based resin, a polyester-based resin, an olefin-based resin, or a polycarbonate-based resin. The base film 310 may be formed of a material (for example, polyethylene terephthalate, polycarbonate, polymethyl metacrylate, polyimid polysulfone, polyestersulfone, fantasy polyolefin, or polyehtylene naphthalate) suitable to form a resin mold having flexibility.

A material of the soluble polymer layer 321 may differ from the material of the polymer layer 231 of FIG. 3A which is used to form the large-area mold 250, and thus, a separation process to be described below with reference to FIG. 3G can be more easily performed, according to at least one example embodiment.

The soluble polymer layer 321 is disposed on the large-area mold 250, and by pressurizing and hardening the soluble polymer layer 321, as illustrated in FIG. 3F, the pattern polymer layer is formed according to at least one example embodiment. Then, as illustrated in FIG. 3G, the large-area mold 250 is separated from the pattern polymer layer 320. In this case, a polymer material forming the large-area mold 250 may differ from a polymer material forming the pattern polymer layer 320, and thus, a release process may be more easily performed.

According to at least one example embodiment, in order to more easily perform the release process, namely, in order to prevent a resin material forming the soluble polymer layer 321 from attaching to the large-area mold 250, a release agent may be applied between the large-area mold 250 and the soluble polymer layer 321. The release agent may include a material that has fixedness with respect to the large-area mold 250, and releasability with respect to the soluble polymer layer 321. A surface of the large-area mold 250 is plasma-processed or is processed with a silane coupling agent, thereby enhancing a fixedness of the release agent. Alternatively, an oxide layer formed of inorganic oxide is formed on the surface of the large-area mold 250, thereby preventing a release layer from deviating from the surface. As another example method, an additive is added into the soluble polymer layer 321, is distributed near a surface of the soluble polymer layer 321 while the additive is being hardened, and is strongly chemically bonded to a release agent coated in a subsequent process. The release agent may be formed of at least one of a fluorine-based silane coupling agent, a perfluoro-compound containing an amino group or a carboxyl group, and a perfluoroether compound containing an amino group or a carboxyl group. Alternatively, the release agent may be formed of at least one of a silane coupling agent, a terminal aminization perfluoro(perfluoroether) compound, and a group of terminal carboxylation perfluoro(perfluoroether) compounds or a compound of the above group and a complex. Such a material may be coated on the soluble polymer layer 321, and a process may be further performed in which the soluble polymer layer 321 is rinsed with a fluorine-based solvent such as, for example, perfluorohexane.

Subsequently, as illustrated in FIG. 3H, according to at least one example embodiment, a metal material is coated on the pattern polymer layer 320, and by hardening the metal material, a master 350 is formed. The metal material may include nickel (Ni), but is not limited thereto. The master 350 may be formed by, for example, an electroforming method or other method.

Subsequently, by dissolving the pattern polymer layer 320, the master 350 is separated from the base film 310. A solvent for dissolving the pattern polymer layer 320 is determined depending on a material of the pattern polymer layer 320. For example, an organic solvent may include an aromatic-based solvent, a ketone-based solvent, a halogen-based solvent, an ether-based solvent, an ester-based solvent, an alcohol-based solvent, dimethyl formamide, dimethylsulfoxide, or diethyl formamide.

The master 350, which is a metal material, is formed by duplicating the shape of the large-area mold 250 of FIG. 3D, which is a polymer material, and may be repeatedly used for manufacturing the optical film.

Subsequently, as illustrated in FIG. 4A, a low refractive index material layer 421 is formed on a base film 410, according to at least one example embodiment. The low refractive index material layer 421 may be hardened, and may be formed of a material having a refractive index of about 1.39 to about 1.44. Also, the low refractive index material layer 421 may be formed of the same material as a sealing material applied to an organic light-emitting panel with the manufactured optical film applied thereto.

According to at least one example embodiment, the master 350 is disposed on the low refractive index material layer 421, and by pressurizing the master 350, as illustrated in FIG. 4B, the low refractive index pattern layer 420 is formed.

According to at least one example embodiment, as illustrated in FIG. 4C, the master 350 is separated from the low refractive index pattern layer 420.

According to at least one example embodiment, as illustrated in FIG. 4D, a high refractive index material layer 521 is formed on a substrate 510. The high refractive index material layer 521 may be coated in the form of droplets by using a nozzle. The high refractive index material layer 521 may be formed of a material having a higher refractive index than the refractive index of the low refractive index material layer 421 of FIG. 4A, and having a high refractive index of about 1.56 to about 1.6 once the material is hardened. A difference between the refractive index of the high refractive index material layer 521 and the refractive index of the low refractive index material layer 421 may be determined so that any color shift based on a viewing angle is reduced. For example, the refractive index difference may be set to a range of about 0.12 to about 0.21.

According to at least one example embodiment, as illustrated in FIG. 4E, the low refractive index pattern layer 420 is imprinted on the high refractive index material layer 521. In this case, a UV irradiation process may be performed so that the shape of the low refractive index pattern layer 420 is transferred to the high refractive index material layer 521, and hardened. Also, a thermal treatment may be performed along with the UV irradiation process. Such a process is performed so that materials forming the high refractive index material layer 521 are fully filled into the pattern of the low refractive index pattern layer 420.

According to at least one example embodiment, as illustrated in FIG. 4F, by removing the base film 410 from the low refractive index pattern layer 420, an optical film 1 of FIG. 4G is manufactured. Also, a thermal treatment process may be further performed as a subsequent process. Such a process removes any voids which may be formed in the process of FIG. 4E, and removes any residual gas remaining in the voids. When a subsequent process is performed, it may be confirmed that gases remaining in a pattern are reduced.

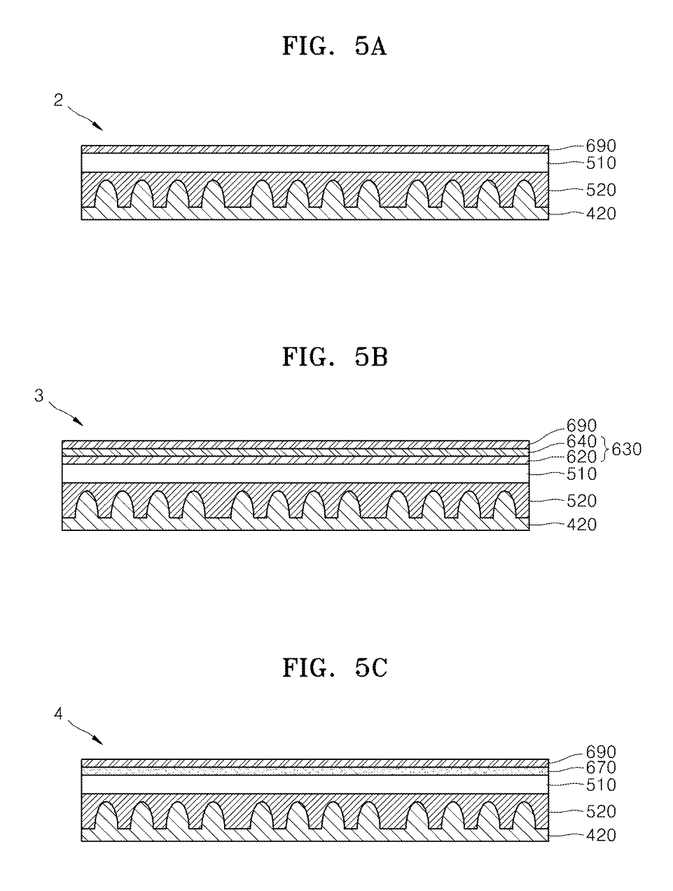

FIGS. 5A to 5C are cross-sectional views illustrating structures of an optical film manufactured by the method of manufacturing the optical film according to at least one example embodiment.

Referring to FIG. 5A, an optical film 2 further includes an anti-reflection layer 690, according to at least one example embodiment. That is, the anti-reflection layer 690 is further formed on a surface of the substrate 510 opposite to the surface of the substrate 510 on which the high refractive index pattern layer 520 is formed.

Referring to FIG. 5B, an optical film 3 further includes a circular polarization film 630 that is formed between the substrate 510 and the anti-reflection layer 690, the circular polarization film 630 including a phase conversion layer 620 and a linear polarization layer 640, according to at least one example embodiment.

The circular polarization film 630, including the phase conversion layer 620 and the linear polarization layer 640, reduces reflectivity of external light to increase visibility. When external non-polarized light is incident, the external light is changed to a linear polarization light by passing through the linear polarization layer 640, and is circularly polarized by the phase conversion layer 620. The circularly polarized light passes through the substrate 510, the high refractive index pattern layer 520, and the low refractive index pattern layer 420, and is then reflected at an interface of an organic light-emitting panel (not shown) to be changed to a circular-polarization light having an opposite rotational direction. In addition, the circular-polarization light is changed to a linear-polarization light having a transmittance axis that is vertical to the axis of the linear polarization layer 640 by passing through the phase conversion layer 620, and is thus not output to the outside.

Referring to FIG. 5C, an optical film 4 includes a transmittance adjusting layer 670 that is formed between the substrate 510 and the anti-reflection layer 690, according to at least one example embodiment.

The transmittance adjusting layer 670 may be a film formed by dispersing, as a light-absorbing black material, a black dye, a pigment, carbon black, or a bridging particle (of which a surface is coated with at least one of the above materials) onto a polymer resin. The polymer resin may be an acryl-based UV hardening resin in addition to a binder such as poly(methyl methacrylate) (PMMA), but is not limited thereto. Also, a thickness of the transmittance adjusting layer 670 or a content of black materials contained in the polymer resin may be appropriately determined depending on optical properties of the black materials. A transmittance of the transmittance adjusting layer 670 may be 40% or more, which is slightly higher than a transmittance of the circular polarization film. The transmittance adjusting layer 670 reduces a disadvantage of having the circular polarization film completely blocking external light while having a low transmittance.

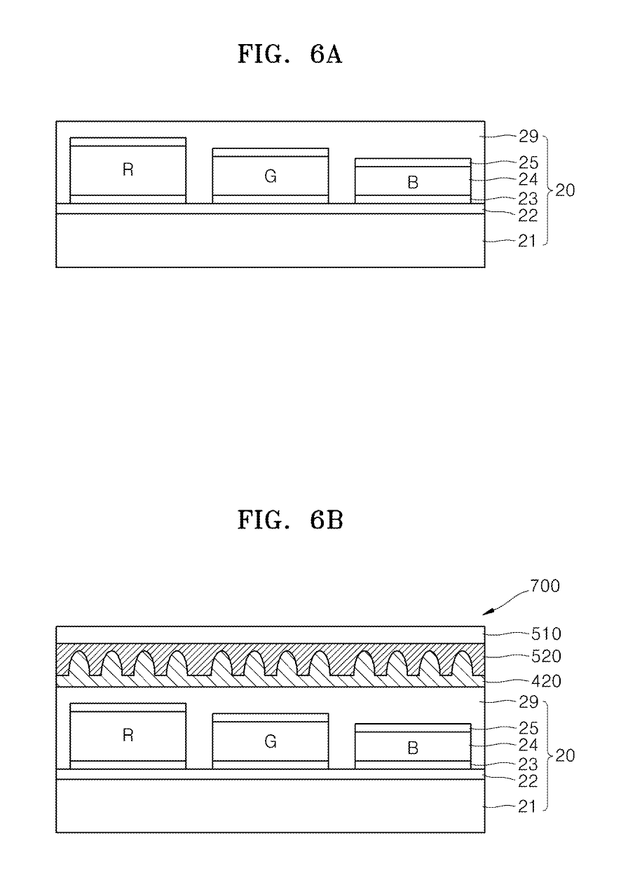

FIGS. 6A to 6B describe a method of manufacturing an organic light-emitting display apparatus according to an example embodiment.

As illustrated in FIG. 6A, an organic light-emitting panel 20 is prepared, according to at least one example embodiment. The organic light-emitting panel 20 includes a plurality of organic emission layers 24, each of which emits light of different wavelengths and has a micro-cavity structure causing a resonance phenomenon for light having a corresponding wavelength, and a sealing layer 29 that covers the organic emission layers 24. Here, the organic emission layers 24 and the sealing layer 29 are formed on the substrate 21.

A driving circuit unit 22 for controlling an amount of current supplied to the organic emission layers 24 is disposed on the substrate 21.

Each of the organic emission layers 24 may include a hole injection layer (HIL), a hole transport layer (HTL), an electron transport layer (ETL), and an electron injection layer (EIL), which are sequentially stacked in a direction from an anode 23 to a cathode 25. When a forward voltage is applied between the anode 23 and the cathode 25, electrons move from the cathode 25 to the corresponding or adjacent organic emission layer 24 through the EIL and the ETL, and holes move from the anode 23 to the corresponding organic emission layer 24 through the HIL and the HTL. The holes and electrons injected into the corresponding organic emission layer 24 are recombined in the corresponding organic emission layer 24 to generate excitons, and the excitons are shifted from an excited state to a ground state, and thus, light is emitted. Here, a brightness of the emitted light is proportional to an amount of current flowing between the anode 23 and the cathode 25.

Each of the organic emission layers 24 has a micro-cavity structure, and thus light emitted from the organic emission layer 24 and having a certain wavelength resonates to increase the intensity of light, and is output to the outside. To this end, a distance between the anode 23 and the cathode 25 is designed to match a representative wavelength of each of red (R), green (G), and blue (B), and to be different for each pixel.

Since a function of the organic emission layers 24 is damaged when an organic material forming the organic emission layers 24 contacts air, the sealing layer 29 is formed to prevent such contact and to protect the organic emission layers 24. The sealing layer 29 may be formed of the same material as the material of the low refractive index pattern layer 420 included in the optical film.

As illustrated in FIG. 6B, the optical film 1 is bonded to the organic light-emitting panel 20, according to at least one example embodiment. To this end, an adhesive material may be used, and a hardening process that irradiates UV may be performed. The adhesive material uses a material that has a refractive index matching the refractive index of each of the low refractive index pattern layer 420 and the sealing layer 29.

In an organic light-emitting display apparatus 700 manufactured by using the above-described example method, color shift due to a change in viewing angle is reduced by using a micro-lens array pattern formed by an interface between the high refractive index pattern layer 520 and the low refractive index pattern layer 420. However, an image may be distorted (blurred) by the micro-lens array pattern. In order to reduce the distortion of the image, a distance between the micro-lens array pattern and each of the organic emission layers is reduced, and may be set to about 1.5 mm or less. The organic light-emitting display apparatus 700 according to an example embodiment may have a structure in which the high refractive index pattern layer 520 and the low refractive index pattern layer 420 are formed inside the substrate 510, thereby minimizing a distance between each of the organic emission layers 24 and the micro-lens array pattern.

The optical film 1 of FIG. 4G is illustrated as being bonded to the organic light-emitting panel 20. However, the optical films 2 to 4 of FIGS. 5A to 5C may also be applied.

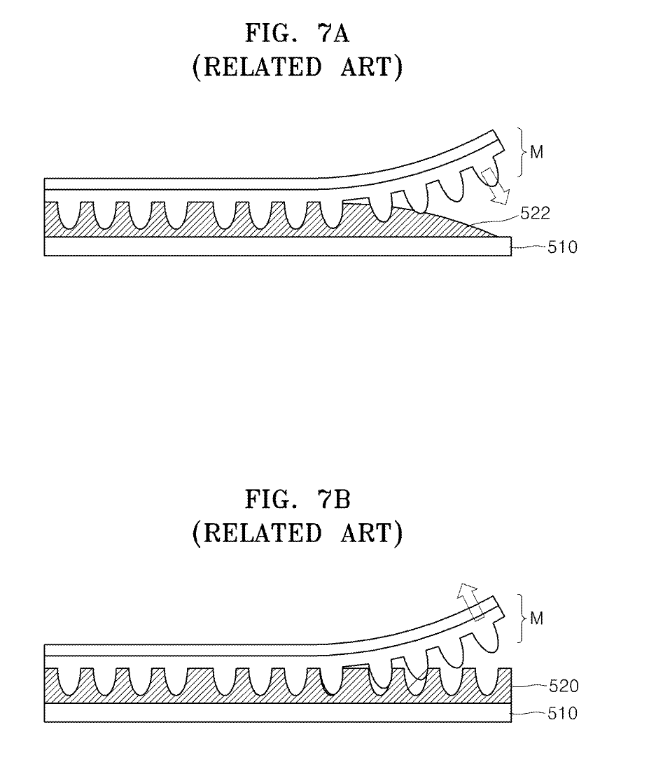

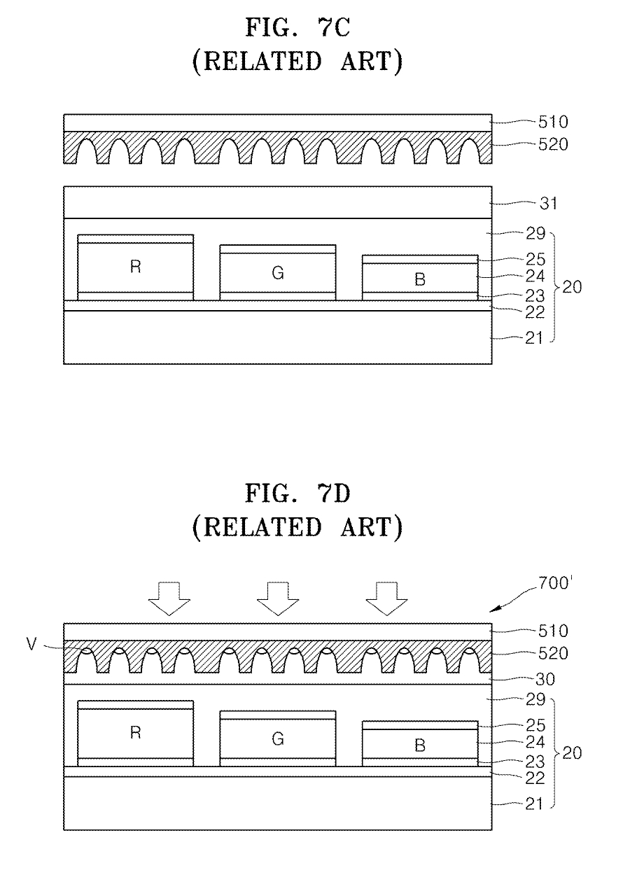

FIGS. 7A to 7E describe a method of manufacturing an organic light-emitting display apparatus according to a comparative example.

Referring to FIG. 7A, a liquid polymer layer 522 is formed on the substrate 510, and a mold M (in which a pattern to be transferred to the polymer layer 522 is embossed) is imprinted on the polymer layer 522.

By hardening the liquid polymer layer 522 through UV irradiation along with a pressurization process, as illustrated in FIG. 7A, the high refractive index pattern layer 520, in which the shape of the mold M is engraved by an imprint process, is formed. Subsequently, the mold M is separated from the high refractive index pattern layer 520. In such a release process, various defects typically occur. In order to facilitate the release process, a method may be used in which surface energy of the mold M is lowered, and an adhesive force between the mold M and the high refractive index pattern layer 520 is reduced. The method reduces a plug defect which occurs in the release process, namely, by preventing a portion of a pattern from being separated. To this end, a self-assembled monolayer may be coated to have a functional group having low surface energy, in which case a time taken to fill a polymer material into the pattern of the mold M increases to cause a non-fill defect.

Subsequently, referring to FIGS. 7C and 7D, a low refractive index material layer 31 is formed on the organic light-emitting panel 20, and the high refractive index pattern layer 520 is imprinted thereon. The low refractive index material layer 31 is illustrated as being separated from the sealing layer 29. However, the high refractive index pattern layer 520 is imprinted on the sealing layer 29, and thus, a portion of the sealing layer 29 may become a low refractive index material layer that is a portion of the optical film.

When the high refractive index pattern layer 520 pressurizes the low refractive index material layer 31, and materials forming the low refractive index material layer 31 are filled into a pattern of the high refractive index pattern layer 520 as a result, a void V may be formed due to the viscosity and surface energy of the pattern of the high refractive index pattern layer 520. Outgassing occurring in the void V affects a service life of an OLED, and the void V is reduced by a post-curing process described above with reference to FIG. 4G.

In a manufacturing method according to the comparative example, there is a high possibility that a plug defect occurs in the process of FIG. 7B, and a void defect occurs in the process of FIG. 7D. However, the manufacturing method according to an example embodiment does not perform the processes of FIGS. 7B and 7D, thereby preventing defects from occurring.

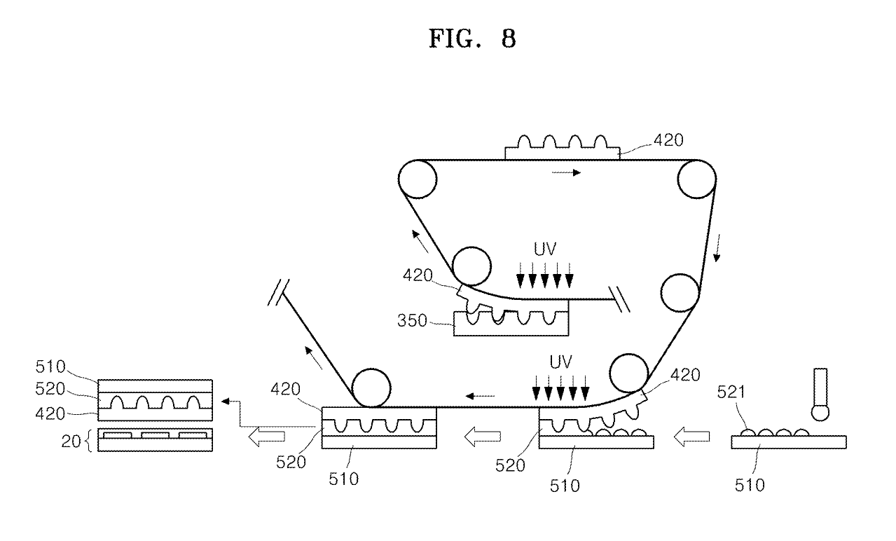

FIG. 8 describes a method of manufacturing an organic light-emitting display apparatus according to at least one example embodiment.

The low refractive index pattern layer 420 may be formed by using the master 350 that is formed via the processes of FIGS. 3A to 3I, and the high refractive index material layer 521 may be coated on the substrate 510. The low refractive index pattern layer 420 may then be disposed on the high refractive index material layer 521, and pressurized, and a series of processes of forming the high refractive index pattern layer 520 may be continuously, repeatedly performed according to a roll printing process.

It is illustrated that UV is irradiated in a hardening process, but this is merely an example. A heat-hardening process may be selected, or may be performed along with the hardening process.

By performing such a process, the repeated mass production of the optical film 1 is achieved. An organic light-emitting apparatus may be manufactured by a simple process that bonds the manufactured optical film 1 to the organic light-emitting panel 20.

Hereinabove, the micro-lens array pattern is merely an example, and various shapes may be applied in consideration of the reduction effect of color shift. Also, a pattern shape or an arrangement period of a position corresponding to each pixel may be differently designed.

The above-described optical film manufacturing method forms the micro-lens array pattern on the interface between the low refractive index pattern layer and the high refractive index pattern layer, and the low refractive index pattern layer is used as the imprinting mold for forming the high refractive index pattern layer. Therefore, the release process that separates the imprinting mold from the high refractive index pattern layer may not be performed, and thus, the micro-lens array pattern with reduced defects may be formed.

As described above, according to one or more of the example embodiments, the optical film manufactured by the above-described example method is bonded to the organic light-emitting panel by using a simple method.

In the above-described organic light-emitting display apparatus, the organic emission layer is formed to have the micro-cavity structure with enhanced color purity, and thus, color shift caused by a changing viewing angle is reduced, thereby providing a high-quality image. Also, by providing a structure in which the optical film for reducing color shift is disposed in the substrate, the distance between the organic emission layer and the optical film is minimized, and thus, image blurring caused by the optical film is minimized.

It should be understood that the example embodiments described herein should be considered in a descriptive sense only and not for purposes of limitation. Descriptions of features or example embodiments should typically be considered as available for other similar features in other embodiments.

While one or more example embodiments have been described with reference to the figures, it will be understood by those of ordinary skill in the art that various changes in form and details may be made therein without departing from the spirit and scope of the example embodiments as defined by the following claims.

What is claimed is:

1. An optical film manufacturing method comprising:
forming a master in which a shape corresponding to a plurality of projected micro-lens patterns is formed;
forming a low refractive index pattern layer in which the plurality of micro-lens patterns are formed via the master; and
forming a high refractive index material layer that has a higher refractive index than a refractive index of the low refractive index pattern layer, and imprinting the low refractive index pattern layer on the high refractive index material layer to form a high refractive index pattern layer, on a first surface of a substrate.

2. The optical film manufacturing method of claim 1, wherein after the imprinting, a release process that separates the low refractive index pattern layer from the high refractive index pattern layer is not performed.

3. The optical film manufacturing method of claim 1, wherein the forming of the low refractive index pattern layer comprises:
forming a low refractive index material layer on a base film;
disposing the master on the low refractive index material layer;
applying pressure on the master and hardening the master to form the low refractive index pattern layer; and
separating the master from the low refractive index pattern layer.

4. The optical film manufacturing method of claim 3, further comprising separating the base film from the low refractive index pattern layer after the high refractive index pattern layer is formed.

5. The optical film manufacturing method of claim 1, wherein the forming of the master comprises:
forming a plurality of sub-molds that are each formed of a resin material and that have a same shape as a shape of a portion of the master;
adding the plurality of sub molds together to form a large-area mold; and
duplicating the large-area mold to form a shape of the large-area mold by using a metallic material.

6. The optical film manufacturing method of claim 5, wherein the forming of the plurality of sub molds comprises:
forming a metal mold in which a shape corresponding to the sub-mold is embossed;
imprinting the shape of the metal mold on a first polymer material;
separating the metal mold from the first polymer material to form one sub-mold; and
repeating the imprinting for a second polymer material.

7. The optical film manufacturing method of claim 6, wherein the forming of the metal mold comprises:
forming a silicon master in which the plurality of micro-lens patterns are embossed; and
duplicating the silicon master to form a metal master having a same shape as a shape of the silicon master.

8. The optical film manufacturing method of claim 7, wherein the forming of the silicon master comprises using an electron beam lithography method or a laser interference lithography method.

9. The optical film manufacturing method of claim 7, wherein the duplicating of the silicon master comprises:
forming a soluble polymer layer on a base film;
disposing the silicon master on the soluble polymer layer;
applying pressure on the silicon master and hardening the silicon master to form a pattern polymer layer;
separating the silicon master from the pattern polymer layer;
coating a metal material on the pattern polymer layer
hardening the metal material; and
dissolving the pattern polymer layer.

10. The optical film manufacturing method of claim 9, wherein the soluble polymer layer includes polyvinylalcohol.

11. The optical film manufacturing method of claim 5, wherein duplicating the large-area mold comprises:
forming a soluble polymer layer on a base film;
disposing the large-area mold on the soluble polymer layer;
applying pressure on the large-area mold and hardening the large-area mold to form a pattern polymer layer;
separating the pattern polymer layer from the large-area mold;
coating a metal material on the pattern polymer layer
hardening the metal material; and
dissolving the pattern polymer layer.

12. The optical film manufacturing method of claim 11, wherein the soluble polymer layer includes polyvinylalcohol.

13. The optical film manufacturing method of claim 1, wherein the forming of the low refractive index pattern layer and the forming of the high refractive index pattern layer comprise a roll printing process.

14. The optical film manufacturing method of claim 1, further comprising forming an anti-reflection layer on a second surface of the substrate facing the first surface.

15. The optical film manufacturing method of claim 14, further comprising forming a circular polarization film that includes a phase conversion layer and a linear polarization layer on the second surface before forming the anti-reflection layer.

16. The optical film manufacturing method of claim 14, further comprising forming a transmittance adjusting layer on the second surface before forming the anti-reflection layer.

17. A method of manufacturing an organic light-emitting display apparatus comprising:
preparing an organic light-emitting panel, the organic light-emitting panel including a plurality of organic emission layers, each of which emitting light at different wavelengths and having a micro-cavity structure causing a resonance phenomenon with respect to light having a corresponding wavelength, and a sealing layer covering the plurality of organic emission layers;
manufacturing an optical film according to the method of claim 1; and
bonding the optical film to the organic light-emitting panel.

18. The method of claim 17, wherein the sealing layer and the low refractive index pattern layer are formed of a same material.

19. An organic light-emitting display apparatus comprising:
a first substrate;
a plurality of organic emission layers on the first substrate, each of which emitting light at different wavelengths and having a micro-cavity structure causing a resonance phenomenon with respect to light having a corresponding wavelength;
a sealing layer covering the plurality of organic emission layers;
a low refractive index pattern layer on the sealing layer, and in which a plurality of micro-lens patterns are embossed;
a high refractive index pattern layer on the low refractive index pattern layer, the high refractive index pattern layer having a higher refractive index than a refractive index of the low refractive index pattern layer, and in which a shape corresponding to the plurality of micro-lens pattern is engraved; and
a second substrate formed on the high refractive index pattern layer.

20. The organic light-emitting display apparatus of claim 19, wherein the sealing layer and the low refractive index pattern layer are formed of a same material.
